(19) United States
(12) Patent Application Publication
(10) Pub. No.: US 2023/0080062 A1
(43) Pub. Date: Mar. 16, 2023

(54) MULTI-ELECTRON BEAM INSPECTION APPARATUS AND ADJUSTMENT METHOD FOR THE SAME

(71) Applicant: Nuflare Technology, Inc., Yokohama-shi (JP)

(72) Inventors: Koichi ISHII, Yokohama-shi (JP); Kazuhiko INOUE, Yokohama-shi (JP); Shohei MIKAMI, Yokohama-shi (JP); Toshikatsu AKIBA, Yokohama-shi (JP)

(73) Assignee: Nuflare Technology, Inc., Yokohama-shi (JP)

(21) Appl. No.: 18/056,511

(22) Filed: Nov. 17, 2022

Related U.S. Application Data
(63) Continuation of application No. PCT/JP2021/017621, filed on May 10, 2021.

(30) Foreign Application Priority Data
Aug. 19, 2020 (JP) 2020-138777

(51) Int. Cl. G01N 23/2251

(52) U.S. Cl. CPC G01N 23/2251; G01N 2223/20; G01N 2223/6116; G01N 2223/07; G01N 2223/507

(57) ABSTRACT

According to the present invention, a desired one of multiple beams can be aligned with a small-diameter aperture quickly. A multi-electron beam inspection apparatus includes a beam selection aperture substrate including a first passage hole that passes all the multiple electron beams, a second passage hole through which one of the multiple electron beams is able to pass, a first slit, and a second slit not parallel to the first slit, an aperture moving unit moving the beam selection aperture substrate, a first detector detecting a current of a beam having passed through the first slit and a current of a beam having passed through the second slit, of the multiple electron beams, and a second detector detecting multiple secondary electron beams including reflected electrons, discharged from a substrate, due to application of the multiple electron beams, having passed through the first passage hole, to the substrate. The substrate is inspected based on an output signal from the second detector.

### TECHNICAL FIELD

The present invention relates to a multi-electron beam inspection apparatus and adjustment method for the multi-electron beam inspection apparatus.

### BACKGROUND ART

As LSI circuits are increasing in density, the line width of circuits of semiconductor devices is becoming finer. To form a desired circuit pattern onto a semiconductor device, a method of reducing and transferring, by using a reduction-projection exposure apparatus, onto a wafer a highly precise original image pattern formed on a quartz is employed.

An improvement in yield is indispensable for the fabrication of LSI, which takes a massive fabrication cost. With miniaturization of the dimensions of the LSI pattern formed on a semiconductor wafer, the dimensions of pattern defects to be detected are also extremely small. Thus, high precision of a pattern inspection apparatus that inspects a hyperfine pattern transferred onto a semiconductor wafer for defects is needed.

Pattern defects of a mask used in exposing and transferring a hyperfine pattern on a semiconductor wafer with a photolithography technology are one of factors to decrease the yield. For this reason, high precision of a pattern inspection apparatus that inspects a transfer mask used in LSI fabrication for defects is needed.

As an inspection method for pattern defects, there is known a method of comparing a measurement image obtained by capturing a pattern formed on a substrate, such as a semiconductor wafer and a lithography mask, with design data or a measurement image obtained by capturing the same pattern on the substrate. Examples of the inspection method include “die-to-die inspection” that compares pieces of measurement image data obtained by capturing the same patterns at different locations on the same substrate and “die-to-database inspection” that generates design image data (reference image) based on pattern-designed design data and that compares the design image data with a measurement image that is measurement data obtained by capturing a pattern. When the compared images do not match, it is determined that there are pattern defects.

There has been developing an inspection apparatus that acquires a pattern image by scanning on a substrate to be inspected with electron beams and detecting secondary electrons emitted from the substrate with application of electron beams. Development of an apparatus using multiple beams as an inspection apparatus using electron beams has been proceeding. In application of multiple beams, adjustment of the inspection apparatus is performed to correct the blur and distortion of beams.

In adjustment of the inspection apparatus, a specific beam can be selected and used from among multiple beams. Hitherto, to select a specific beam, an aperture substrate 800 provided with a small-diameter aperture 810 that passes only a beam, as shown in FIG. 16, is two-dimensionally scanned with multiple beams 820, and a beam that has passed through the small-diameter aperture 810 is detected with a detector. A signal is detected by the detector each time any one of the multiple beams 820 passes through the small-diameter aperture 810. An image (multi-beam image) showing a beam distribution is generated from the detected position of each beam and the amount of movement of the aperture substrate 800, and the aperture substrate 800 is disposed such that the intended beam passes through the small-diameter aperture 810.

However, such an existing method takes massive time to adjust an inspection apparatus since the aperture substrate needs to be two-dimensionally scanned such that each of the multiple beams 820 passes through the small-diameter aperture 810 to obtain a multi-beam image, adjustment of the position of the aperture substrate itself is needed because multiple beams do not always pass through the small-diameter aperture 810 even with two-dimensional scanning and is accompanied by adjustment of the position of the aperture substrate itself, and other reasons.
PTL 1: JP 2005-317412 A
PTL 2: JP 2006-024624 A
PTL 3: JP 2019-204694 A
PTL 4: JP 2018-067605 A
PTL 5: JP 2019-036403 A

### SUMMARY OF INVENTION

It is an object of the present invention to provide a multi-electron beam inspection apparatus capable of quickly aligning a desired one of multiple beams with a small-diameter aperture, and an adjustment method therefor.

According to one aspect of the present invention, a multi-electron beam inspection apparatus includes an electron gun discharging an inspection electron beam, an aperture array substrate including a plurality of passage holes, wherein part of the inspection electron beam passes through each of the plurality of passage holes to form multiple electron beams, a beam selection aperture substrate including a first passage hole that passes all the multiple electron beams, a second passage hole through which one of the multiple electron beams is able to pass, a first slit, and a second slit not parallel to the first slit, an aperture moving unit moving the beam selection aperture substrate, a first detector detecting a current of a beam having passed through the first slit and a current of a beam having passed through the second slit, of the multiple electron beams, and a second detector detecting multiple secondary electron beams including reflected electrons, discharged from an inspected substrate mounted on a stage, due to application of the multiple electron beams, having passed through the first passage hole, to the inspected substrate, wherein the inspected substrate is inspected based on an output signal from the second detector.

According to one aspect of the present invention, an adjustment method is for a multi-electron beam inspection apparatus that inspects a pattern by detecting multiple secondary electron beams including reflected electrons, discharged from a substrate having a formed pattern, due to application of multiple electron beams to the substrate, and using information of the detected multiple secondary electron beams. The adjustment method includes a step of, while moving, in a predetermined direction, a beam selection aperture substrate including a passage hole through which one of the multiple electron beams is able to pass, a first slit, and a second slit not parallel to the first slit, detecting a current of a beam having passed through the first slit, of the multiple electron beams, a step of, while moving the beam selection aperture substrate in the predetermined direction, detecting a current of a beam having passed through the second slit, of the multiple electron beams, a step of calculating distribution information of the multiple electron beams based on detection results of currents of beams having passed through the first slit and detection results of currents of beams having passed through the second slit, a step of aligning a predetermined beam of the multiple electron beams with the passage hole by moving the beam selection aperture substrate based on the distribution information of the multiple electron beams, and a step of performing beam adjustment by using a beam having passed through the passage hole.

### Advantageous Effects of Invention

According to the present invention, it is possible to quickly align a desired one of multiple beams with a small-diameter aperture.

### BRIEF DESCRIPTION OF DRAWINGS

FIG. 1 is a schematic configuration diagram of a pattern inspection apparatus according to an embodiment of the present invention.

FIG. 2 is a plan view of a forming aperture array substrate.

FIG. 3 is a plan view of a beam selection aperture substrate.

FIGS. 4a and 4b are diagrams showing an example of scanning of slits.

FIG. 5a is a view showing an example of a detection result when the slits are scanned, and FIG. 5b is a view showing an example of multiple beams.

FIG. 6a is a view showing an example of a detection result when the slits are scanned, and FIG. 6b is a view showing an example of coordinate transformation.

FIG. 7 is a view showing a beam presence range of multiple beams;

FIGS. 8a and 8b are diagrams showing examples of rotation of multiple beams.

FIGS. 9a and 9b are graphs showing examples of detection results when the slits are scanned.

FIG. 10 is a plan view of a beam selection aperture substrate.

FIG. 11 is a view showing a beam presence range of multiple beams.

FIG. 12 is a plan view of a beam selection aperture substrate.

FIG. 13 is a graph showing an example of detection results when an opening is scanned.

FIGS. 14a and 14b are graphs showing an example of detection results when the opening is scanned.

FIG. 15 is a plan view of the beam selection aperture substrate.

FIG. 16 is a diagram showing an example of scanning of a small-diameter aperture.

### DESCRIPTION OF EMBODIMENTS

Hereinafter, in an embodiment, a structure that captures a secondary electron image by applying multiple beams that are electron beams to an inspected substrate will be described as an example of a method of capturing a pattern (acquiring an inspected image) formed on the inspected substrate.

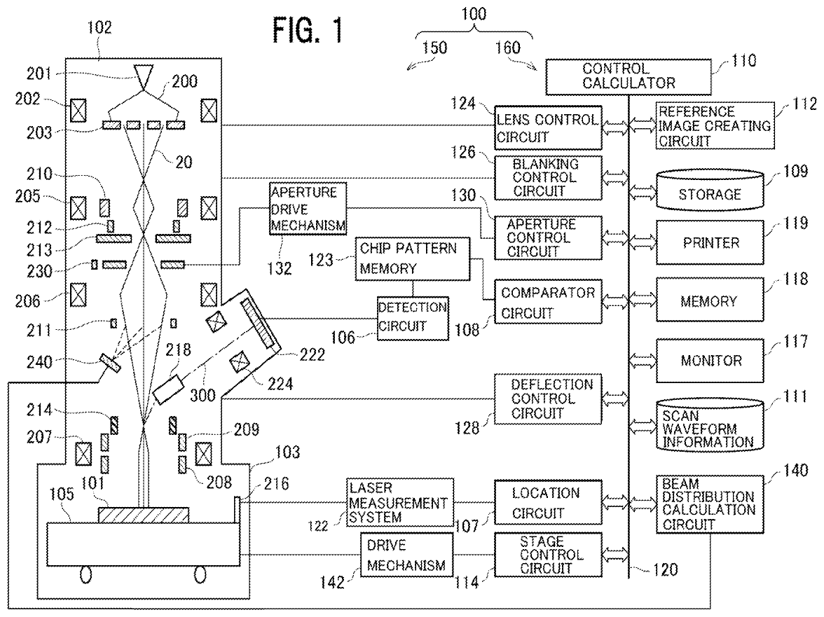

FIG. 1 shows the schematic configuration of a pattern inspection apparatus according to the embodiment of the present invention. In FIG. 1, an inspection apparatus 100 that inspects a pattern formed on a substrate is an example of an electron beam inspection apparatus. The inspection apparatus 100 is an example of a multi-beam inspection apparatus. The inspection apparatus 100 is also an example of an electron beam image acquisition apparatus. The inspection apparatus 100 is also an example of a multi-beam image acquisition apparatus.

As shown in FIG. 1, the inspection apparatus 100 includes an image acquisition mechanism 150 and a control system circuit 160. The image acquisition mechanism 150 includes an electron beam column 102 (electron lens barrel) and an inspection chamber 103. An electron gun 201, an electromagnetic lens 202, a forming aperture array substrate 203, an electromagnetic lens 205, an electrostatic lens 210, a collective blanking deflector 212, a limiting aperture substrate 213, a beam selection aperture substrate 230, an electromagnetic lens 206, a deflector 211, a detector 240 (first detector), an electromagnetic lens 207 (objective lens), a main deflector 208, a sub-deflector 209, a beam separator 214, a deflector 218, an electromagnetic lens 224, and a multi-detector 222 (second detector) are disposed in the electron beam column 102.

A stage 105 that is movable in X, Y, and Z directions is disposed in the inspection chamber 103. A substrate 101 (sample) that is a target to be inspected is placed on the stage 105. The substrate 101 includes an exposure mask substrate and a semiconductor substrate, such as a silicon wafer. When the substrate 101 is a semiconductor substrate, a plurality of chip patterns (wafer dies) is formed on the semiconductor substrate. When the substrate 101 is an exposure mask substrate, a chip pattern is formed in the exposure mask substrate. A chip pattern is composed of a plurality of geometric shape patterns. When a chip pattern formed on an exposure mask substrate is exposed and transferred onto a semiconductor substrate multiple times, a plurality of chip patterns (wafer dies) is formed on the semiconductor substrate.

The substrate 101 is placed on the stage 105 such that a pattern forming surface is faced upward. A mirror 216 is disposed on the stage 105. The mirror 216 reflects a laser beam for laser measurement, applied from a laser measurement system 122 disposed outside the inspection chamber 103.

The multi-detector 222 is connected to a detection circuit 106 outside the electron beam column 102. The detection circuit 106 is connected to a chip pattern memory 123.

In the control system circuit 160, a control calculator 110 that controls the overall inspection apparatus 100 is connected to a location circuit 107, a comparator circuit 108, a reference image creating circuit 112, a stage control circuit 114, a lens control circuit 124, a blanking control circuit 126, a deflection control circuit 128, an aperture control circuit 130, a beam distribution calculation circuit 140, storage devices 109, 111, such as a magnetic disk device, a monitor 117, a memory 118, and a printer 119 via a bus 120.

The deflection control circuit 128 is connected to the main deflector 208, the sub-deflector 209, the deflector 211, and the deflector 218 via a DAC (digital-to-analog conversion) amplifier (not shown).

The chip pattern memory 123 is connected to the comparator circuit 108.

The stage 105 is driven by a drive mechanism 142 under control of the stage control circuit 114. The stage 105 is movable in a horizontal direction and in a rotation direction. The stage 105 is movable in a height direction.

The laser measurement system 122 measures the position of the stage 105 based on the principle of laser interferometry by receiving reflected light from the mirror 216. A moved position of the stage 105, measured by the laser measurement system 122, is informed to the location circuit 107.

The electromagnetic lens 202, the electromagnetic lens 205, the electromagnetic lens 206, the electromagnetic lens 207 (objective lens), the electrostatic lens 210, the electromagnetic lens 224, and the beam separator 214 are controlled by the lens control circuit 124.

The electrostatic lens 210 is made up of, for example, three or more stages of electrode substrates of which the center is open. The intermediate electrode substrate is controlled by the lens control circuit 124 via a DAC amplifier (not shown). The top and bottom electrode substrates of the electrostatic lens 210 are applied with a ground potential.

The collective blanking deflector 212 is made up of two or more electrodes, and is controlled by the blanking control circuit 126 via a DAC amplifier (not shown) electrode by electrode.

The sub-deflector 209 is made up of four or more electrodes and is controlled by the deflection control circuit 128 via a DAC amplifier electrode by electrode. The main deflector 208 is made up of four or more electrodes and is controlled by the deflection control circuit 128 via a DAC amplifier electrode by electrode. The deflector 218 is made up of four or more electrodes and is controlled by the deflection control circuit 128 via a DAC amplifier electrode by electrode. The deflector 211 is made up of two or more electrodes and is controlled by the deflection control circuit 128 via a DAC amplifier electrode by electrode.

The beam selection aperture substrate 230 is disposed on the downstream side of the limiting aperture substrate 213 and on the upstream side of the deflector 211 in the traveling direction of multiple beams 20 and is capable of selectively solely passing an individual beam or passing all the beams of the multiple beams 20. The beam selection aperture substrate 230 is driven by an aperture drive mechanism 132 under control of the aperture control circuit 130. The beam selection aperture substrate 230 is movable in the horizontal direction (the X direction and the Y direction).

The detector 240 detects the current of a beam deflected by the deflector 211. A detection signal of the detector 240 is output to the beam distribution calculation circuit 140. For example, a Faraday cup or a photodiode may be used as the detector 240.

A high-voltage power supply circuit (not shown) is connected to the electron gun 201. By application of an acceleration voltage from the high-voltage power supply circuit to between a lead-out electrode (anode) and a filament (cathode) (not shown) in the electron gun 201 and, in addition, application of the voltage of another lead-out electrode (Wehnelt) and heating of the cathode at a predetermined temperature, an electron group discharged from the cathode is accelerated and emitted as an electron beam 200.

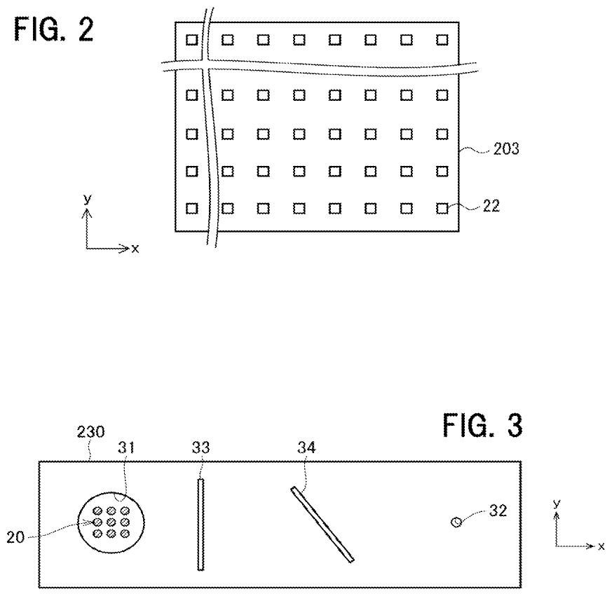

FIG. 2 is a conceptual view showing the configuration of the forming aperture array substrate 203. Openings 22 are two-dimensionally formed at a predetermined arrangement pitch in the x direction and the y direction on the forming aperture array substrate 203. The openings 22 all have the same rectangular or circular shape and dimensions. When part of the electron beam 200 passes through each of the plurality of openings 22, the multiple beams 20 are formed.

Next, the operation of the image acquisition mechanism 150 in the inspection apparatus 100 will be described.

The electron beam 200 discharged from the electron gun 201 (discharge source) is refracted by the electromagnetic lens 202 and illuminates the overall forming aperture array substrate 203. As shown in FIG. 2, the forming aperture array substrate 203 has the plurality of openings 22, and the electron beam 200 illuminates a region in which the plurality of openings 22 is included. Parts of the electron beam 200 applied to the positions of the plurality of openings 22 respectively pass through the plurality of openings 22 to form multiple beams 20 (multiple primary electron beams).

The formed multiple beams 20 are refracted by the electromagnetic lens 205 and the electromagnetic lens 206, pass through a large passage hole 31 (see FIG. 3) of the beam selection aperture substrate 230 and the beam separator 214 disposed at a crossover position of the beams of the multiple beams 20 and travel to the electromagnetic lens 207 (objective lens) while repeating image formation and crossover. Then, the electromagnetic lens 207 focuses the multiple beams 20 on the substrate 101. The multiple beams 20 focused on the surface of the substrate 101 (sample) by the electromagnetic lens 207 are collectively deflected by the main deflector 208 and the sub-deflector 209 and respectively applied to irradiated positions of the beams on the substrate 101.

When the overall multiple beams 20 are collectively deflected by the collective blanking deflector 212, the multiple beams 20 deviate from the center hole of the limiting aperture substrate 213 and are blocked by the limiting aperture substrate 213. On the other hand, the multiple beams 20 not deflected by the collective blanking deflector 212 pass through the center hole of the limiting aperture substrate 213 as shown in FIG. 1. Blanking control is performed by turning on or off the collective blanking deflector 212, and the on or off state of the beams is collectively controlled.

When the multiple beams 20 are applied to desired positions on the substrate 101, a flux of secondary electrons including reflected electrons (multiple secondary electron beams 300), corresponding to the beams of the multiple beams 20 (multiple primary electron beams) is discharged from the substrate 101.

The multiple secondary electron beams 300 discharged from the substrate 101 pass through the electromagnetic lens 207 and travel to the beam separator 214.

The beam separator 214 generates an electric field and a magnetic field in orthogonal directions in a plane orthogonal to a direction in which the central beam of the multiple beams 20 travels (track central axis). The electric field exerts force in the same direction regardless of the traveling direction of electrons. In contrast, the magnetic field exerts force in accordance with Fleming's left-hand rule. Therefore, it is possible to change the direction of force that acts on electrons by using the traveling direction of electrons.

A force based on the electric field and a force based on the magnetic field act on the multiple beams 20 approaching the beam separator 214 from above cancel out each other, and the multiple beams 20 travel downward. In contrast, a force based on the electric field and a force based on the magnetic field act in the same direction on the multiple secondary electron beams 300 approaching the beam separator 214 from below, and the multiple secondary electron beams 300 are deflected obliquely upward and separated from the multiple beams 20.

The multiple secondary electron beams 300 deflected obliquely upward and separated from the multiple beams 20 are deflected by the deflector 218, refracted by the electromagnetic lens 224, and projected to the multi-detector 222. In FIG. 1, the tracks of the multiple secondary electron beams 300 are simply shown without being refracted.

The multi-detector 222 detects the projected multiple secondary electron beams 300. The multi-detector 222 includes, for example, a diode two-dimensional sensor (not shown). Then, at the positions of the diode two-dimensional sensor, corresponding to the beams of the multiple beams 20, secondary electrons of the multiple secondary electron beams 300 collide with the diode two-dimensional sensor to increase electrons in the sensor, and two-dimensional electron image data is generated for each pixel with the amplified signal.

Detected data (measurement image: two-dimensional electron image: inspected image) of secondary electrons detected by the multi-detector 222 is output to the detection circuit 106 in measurement order. In the detection circuit 106, analog detected data is converted to digital data by an A/D converter (not shown), and is stored in the chip pattern memory 123. In this way, the image acquisition mechanism 150 acquires the measurement image of the pattern formed on the substrate 101.

The reference image creating circuit 112 creates a reference image for each mask die based on design data that is a basis for forming the pattern on the substrate 101 or design pattern data defined by exposure image data of the pattern formed on the substrate 101. For example, design pattern data is read from the storage device 109 through the control calculator 110, and each geometric shape pattern defined by the read design pattern data is converted to binary or multivalued image data.

Geometric shapes defined by design pattern data are based on, for example, a rectangle or a triangle. Geometric shape data that defines, for example, the shape, size, position, and the like of each pattern geometric shape is stored in the form of information including the coordinates (x,y) of the reference position of the geometric shape, the length of each side, geometric shape code that is an identifier for identifying a geometric shape type, such as a rectangle and a triangle.

When design pattern data that is geometric shape data is input to the reference image creating circuit 112, the reference image creating circuit 112 develops the design pattern data into data for each geometric shape and interprets the geometric shape code, geometric shape dimensions, and the like representing each geometric shape of the geometric shape data. Then, the reference image creating circuit 112 develops the geometric shape code, geometric shape dimensions, and the like into image data of a binary or multivalued design pattern as a pattern to be arranged in grids with a grid having predetermined quantization dimensions as a unit and outputs the image data.

In other words, design data is read, the occupancy of a geometric shape in a design pattern is computed for each grid imaginarily dividing an inspection region with a grid in predetermined dimensions, and n-bit occupancy data is output. For example, it is suitable that a single grid is set for a pixel. Then, if it is assumed that a pixel has a resolution of ½⁸ (= 1/256), the occupancy in a pixel is computed by allocating 1/256 small regions corresponding to the amount of region of the geometric shape disposed in the pixel. Then, the occupancy is output to the reference image creating circuit 112 as the 8-bit occupancy data. Grids (inspection pixels) should correspond to pixels of measurement data.

Subsequently, the reference image creating circuit 112 appropriately performs filtering on the design image data of a design pattern, that is, the image data of the geometric shape. Optical image data, that is, a measurement image, is in a state where a filter is applied by an optical system, that is, a continuously changing analog state. Therefore, by also applying filtering to the image data of the design pattern, that is the design-side image data of which the image intensities (density values) are digital values, it is possible to match the image data with measurement data. The image data of the created reference image is output to the comparator circuit 108.

The comparator circuit 108 compares the measurement image (inspected image) measured from the substrate 101 with an associated reference image. Specifically, the aligned inspected image and reference image are compared pixel by pixel. Both are compared pixel by pixel in accordance with a predetermined determination condition by using a predetermined determination threshold, and whether there is a defect, such as a shape defect, is determined. When, for example, a gradation value difference of each pixel is greater than the determination threshold Th, it is determined as a defect candidate. Then, the comparison results are output. The comparison results may be stored in the storage device 109 or the memory 118, may be displayed on the monitor 117, or may be printed out from the printer 119.

Other than the above-described die-to-database inspection, die-to-die inspection may be performed. When die-to-die inspection is performed, pieces of measurement image data obtained by capturing the same patterns at different locations on the same substrate 101 are compared. Therefore, the image acquisition mechanism 150 acquires measurement images by using the multiple beams 20 (electron beams). The measurement images are secondary electron images of one geometric shape pattern (first geometric shape pattern) and the other geometric shape pattern (second geometric shape pattern) from the substrate 101 on which the same geometric shape patterns (first and second geometric shape patterns) are formed at different positions. In this case, the acquired measurement image of one geometric shape pattern is a reference image, and the acquired measurement image of the other geometric pattern is an inspected image. The acquired image of one geometric shape pattern (first geometric shape pattern) and the acquired image of the other geometric shape pattern (second geometric shape pattern) may be included in the same chip pattern data or may be separately included in different chip pattern data. The manner of inspection may be similar to the die-to-database inspection.

Before inspection is performed by applying multiple beams to the substrate 101, adjustment work such as focus adjustment and astigmatic adjustment on a sample surface is needed. The adjustment work is not able to be performed by using a plurality of beams, so a specific beam is selected from among multiple beams by using the beam selection aperture substrate 230 and is used for adjustment work.

As shown in FIG. 3, the beam selection aperture substrate 230 has a large passage hole 31 (large-diameter aperture) that passes all the multiple beams 20, a small passage hole 32 (small-diameter aperture) that passes one of the multiple beams 20, and two slits 33, 34. These passage holes and slits are, for example, arranged with a space in the x direction in order of the large passage hole 31, the slit 33, the slit 34, and the small passage hole 32. The x direction is defined as a direction in which the beam selection aperture substrate 230 moves toward a beam central axis.

The diameter of the small passage hole 32 is greater than the size of a beam on the surface of the beam selection aperture substrate 230. The diameter of the small passage hole 32 is less than a value obtained by subtracting the size of a beam from a beam pitch (a space between any adjacent beams). Thus, passage of adjacent two beams through the small passage hole 32 at the same time is prevented.

The slits 33, 34 are provided between the large passage hole 31 and the small passage hole 32. For example, the slit 33 extends in the y direction orthogonal to the x direction, and the slit 34 extends in an inclination direction that makes an angle θ with they direction. Here, the inclination angle θ (an angle at which the extending direction of the slit 33 intersects with the extending direction of the slit 34) is 0°<θ<90° (or 90°<θ<180°). In other words, the slit 34 is not parallel to the slit 33. The extending direction of the slit 34 is not orthogonal to the extending direction of the slit 33. The inclination angle θ is preferably larger than or equal to 5° and smaller than or equal to 85° (or larger than or equal to 95° and smaller than or equal to 175°). However, as will be described later, the inclination angle θ needs to be set to an angle other than 45° or 135°.

The width of each of the slits 33, 34 is less than a value obtained by subtracting the size of a beam from the beam pitch on the surface of the beam selection aperture substrate 230. In order for different beams of the multiple beams 20 not to respectively pass through the slit 33 and the slit 34 at the same time, the slit 33 and the slit 34 are spaced apart by the beam size of the multiple beams 20 or greater.

To align a specific beam of the multiple beams 20 with the small passage hole 32 and pass the specific beam through the small passage hole 32, distribution information of multiple beams (positional information of each beam) needs to be acquired.

In the present embodiment, the multiple beams 20 are sequentially scanned by the slits 33, 34, and beams having passed through each of the slits 33, 34 are deflected by the deflector 211 and detected by the detector 240. The distribution information of multiple beams is acquired from the detection results of the detector 240.

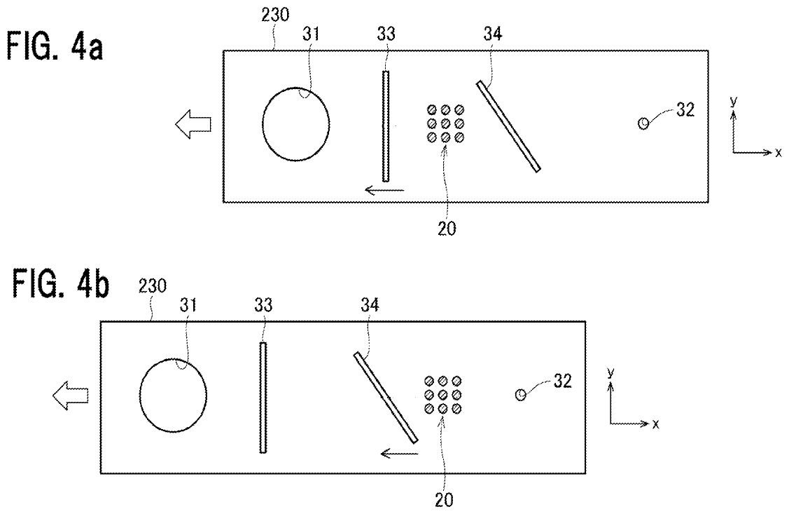

When the multiple beams 20 are scanned by the slits 33, 34, the beam selection aperture substrate 230 is moved by the aperture drive mechanism 132. For example, as shown in FIGS. 4a and 4b, the beam selection aperture substrate 230 is moved in the negative x direction. Thus, the multiple beams 20 relatively move in the positive x direction on the beam selection aperture substrate 230 and are sequentially scanned by the slits 33, 34.

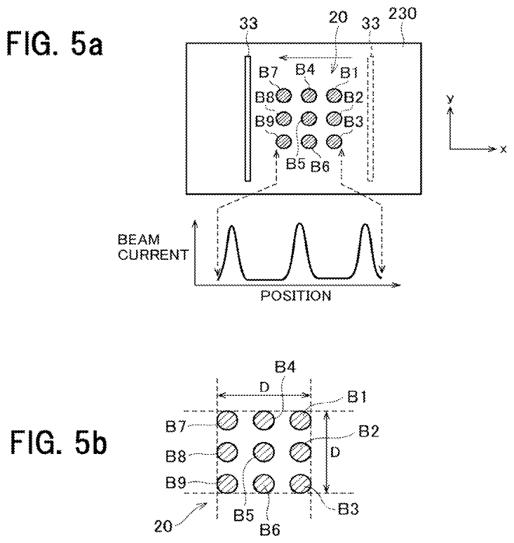

FIG. 5a shows an example of the detection result of the detector 240 when the multiple beams 20 are scanned by the slit 33. Here, for the sake of convenience of description, it is assumed that, as shown in FIG. 5b, the multiple beams 20 are made up of nine (=3×3) beams B1 to B9 and the beam size on the surface of the beam selection aperture substrate 230 is controlled to a constant value D×D. It is assumed that the beams B1 to B9 are arranged at a predetermined pitch in the x direction and the y direction.

As shown in FIG. 5a, a peak appears in the detection result when the beams B1 to B3 pass through the slit 33, or when the beams B4 to B6 pass through the slit 33, or when the beams B7 to B9 pass through the slit 33. The beam distribution calculation circuit 140 acquires information on the amount of movement (the instructed amount of movement) of the beam selection aperture substrate 230 from the aperture control circuit 130, combines the instructed amount of movement with the detected waveform of the detector 240, and calculates the presence range of the multiple beams 20 in the x direction.

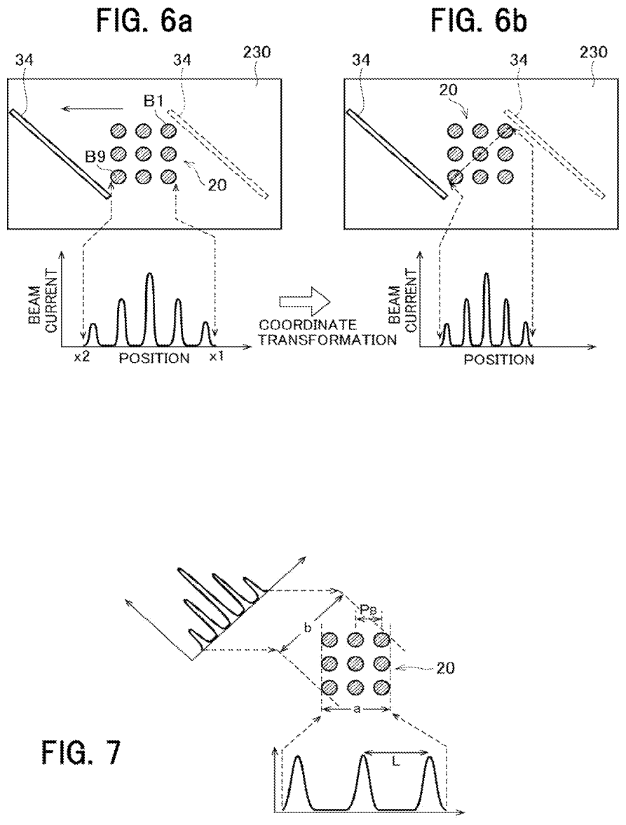

FIG. 6a shows an example of the detection result of the detector 240 when the multiple beams 20 are scanned by the slit 34. The position x1 is a position at which the beam B1 begins to overlap one end side of the slit 34 in the longitudinal direction. The position x2 is a position at which the beam B9 completes passing through the other end side of the slit 34 in the longitudinal direction.

The beam distribution calculation circuit 140 performs coordinate transformation as shown in FIG. 6b in consideration of the inclination angle θ of the slit 34 and calculates the presence range of the multiple beams 20 in an oblique direction (a direction orthogonal to the extending direction of the slit 34). For example, by contracting the waveform shown in FIG. 6a in the x direction (transverse direction in the drawing) such that |x1−x2| becomes |x1−x2|(sin θ+cos θ), the waveform shown in FIG. 6b is obtained.

From the information shown in FIG. 5a ad FIG. 6b, the presence range of the multiple beams 20 is determined as shown in FIG. 7. The beam distribution calculation circuit 140 analyzes the output waveform of the detector 240 and calculates the distribution information of the multiple beams 20.

When the multiple beams 20 are parallel at right angles with respect to the slit 33, the width a of the output waveform of the detector 240 at the time when the multiple beams 20 are scanned by the slit 33 is equal to the beam size D of the multiple beams 20 (a=D), and the width b of the output waveform (transformed waveform) of the detector 240 at the time when the multiple beams 20 are scanned by the slit 34 is b=D(sin θ+cos θ). In this case, it is determined that the beam pitch P_{B} is equal to the peak-to-peak distance L of the output waveform, and the peaks of the waveform coincide with beam positions. The center beam of the multiple beams 20 is located at the center in the beam presence range.

The beam distribution calculation circuit 140 is able to identify the position of each of the beams of the multiple beams 20 from these pieces of information.

When the multiple beams 20 rotate from the position parallel at right angles with respect to the slit 33 and, as a result, the arrangement direction of the beams B1 to B9 is not parallel to the x direction or the y direction, the width a of the output waveform of the detector 240 at the time when the multiple beams 20 are scanned by the slit 33 is greater than the beam size D of the multiple beams 20 (a>D). The width b of the output waveform of the detector 240 at the time when the multiple beams 20 are scanned by the slit 34 is less than D(sin θ+cos θ). The center beam of the multiple beams 20 is located at the center in the beam presence range.

The beam distribution calculation circuit 140 calculates the rotational angle φ and beam pitch P_{B} of the multiple beams 20 by using the following expression.

$$φ = {cos}^{- 1} ( \frac{a \pm \sqrt{2 {D}^{2} - {a}^{2}}}{2 D} ) {P}_{B} = L * cos φ \qquad [ Expression 1 ]$$

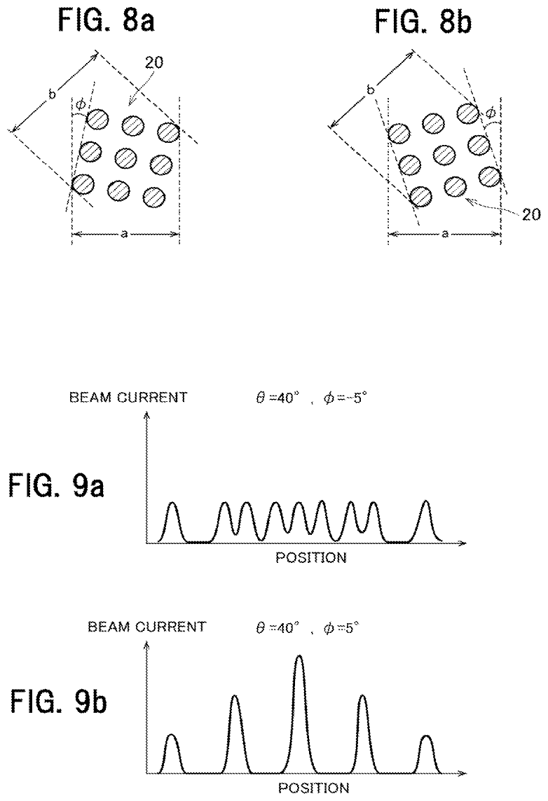

From the above expression, the absolute value of the rotational angle φ of the multiple beams 20 is determined, but the sign is not determined, so the rotational angle φ is not uniquely determined. In other words, as shown in FIGS. 8a and 8b, it is not determined whether the multiple beams 20 are rotated in a clockwise direction or rotated in a counter-clockwise direction.

FIG. 9a shows the output waveform of the detector 240 in the case where the multiple beams 20 rotated by 5° in the counter-clockwise direction are scanned by the slit 34. FIG. 9b shows the output waveform of the detector 240 in the case where the multiple beams 20 rotated by 5° in the clockwise direction are scanned by the slit 34. The inclination angle θ of the slit 34 is set to 40°. As is apparent from FIGS. 9a and 9b, the frequency and peaks of the output waveform of the detector 240 at the time when the multiple beams 20 are scanned by the slit 34 in the case where the multiple beams 20 are rotated in the clockwise direction are different from those in the case where the multiple beams 20 are rotated in the counter-clockwise direction.

Therefore, the output waveforms of the detector 240 at the time when the multiple beams 20 are scanned by the slit 34 for a plurality of rotational angles φ are obtained in advance by changing the rotational angle φ of the multiple beams 20. Alternatively, similar output waveforms are obtained through calculation. The obtained output waveforms are stored in the storage device 111 as scan waveform information.

The beam distribution calculation circuit 140 consults the scan waveform information stored in the storage device 111 and uniquely determines the rotational angle φ of the multiple beams 20 from the frequency and peaks of the output waveform of the detector 240 at the time when the multiple beams 20 are scanned by the slit 34. The beam distribution calculation circuit 140 identifies the position of each of the beams of the multiple beams 20 by using the beam presence range, the beam pitch obtained from the above-described expression, the rotational angle φ obtained from the output waveform, and the like.

When the inclination angle θ of the slit 34 is 45° (when inclined in an opposite direction with reference to the Y-axis (hereinafter, referred to as “in the case of the opposite direction”) is 135°), the output waveform of the detector 240 at the time when the multiple beams 20 are scanned by the slit 34 in the case where the multiple beams 20 are rotated in the clockwise direction is the same as those in the case where the multiple beams 20 are rotated in the counter-clockwise direction, so the rotational angle φ is not able to be uniquely determined. Therefore, as described above, the inclination angle θ of the slit 34 is set to an angle other than 45° (135° in the case of the opposite direction). When the difference between the inclination angle θ of the slit 34 and 45° is Δθ, an waveform difference at the time when the polarity of the rotational angle φ changes is small when Δθ is smaller than or equal to 1° or larger than or equal to 40°. Therefore, it is preferable that the inclination angle θ of the slit 34 is larger than or equal to 5° and smaller than or equal to 44° or larger than or equal to 46° and smaller than or equal to 85° (in the case of the opposite direction, larger than or equal to 95° and smaller than or equal to 134° or larger than or equal to 136° and smaller than or equal to 175°).

In this way, after the position of each of the beams of the multiple beams 20 is identified, the beam selection aperture substrate 230 is moved, and a specific beam is aligned with the small passage hole 32. By using a beam having passed through the small passage hole 32, adjustment work such as focus adjustment and astigmatic adjustment on a sample surface is performed.

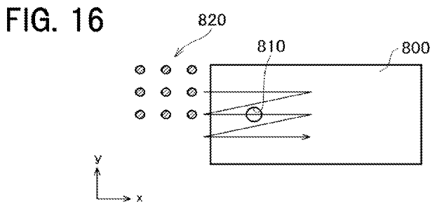

In the present embodiment, the multiple beams 20 are scanned (once) in one direction by the two slits 33, 34, the currents of beams having passed through each of the slits 33, 34 are detected, and the distribution information of multiple beams is obtained from the detected waveform. In comparison with a method of two-dimensionally scanning the small-diameter aperture 810 with the multiple beams 820 as shown in FIG. 16, the distribution information of the multiple beams is easily acquired, and a desired beam of multiple beams is quickly aligned with the small-diameter aperture.

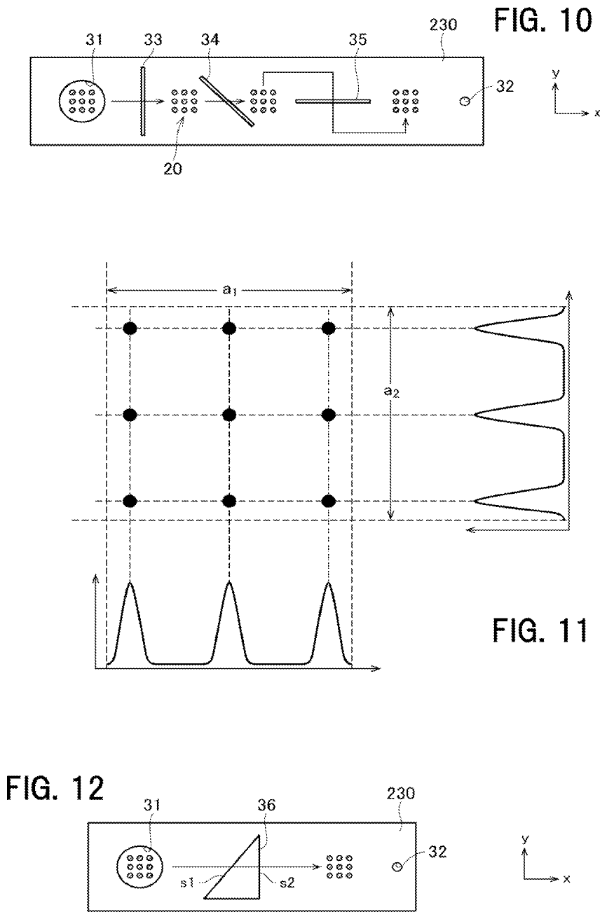

As shown in FIG. 10, the beam selection aperture substrate 230 may further have a slit 35 that extends in a direction orthogonal to the slit 33 (for example, the x direction). When the beam selection aperture substrate 230 is moved such that the slit 35 scans the multiple beams 20 in the y direction, not only the multiple beam presence range (a₁) in the x direction but also the multiple beam presence range (a₂) in the y direction is able to be obtained as shown in FIG. 11. The remaining configuration is similar to that of the above-described embodiment, so, when a₁ or a₂ is equal to D, it is determined that the multiple beams 20 are in a right-angle parallel positional relationship with the beam selection aperture substrate 230, and, when a₁ or a₂ is greater than D, it is determined that the multiple beams 20 are rotated from the right-angle parallel position. The slit 34 is used to identify the angle in the case where the multiple beams 20 are rotated. When the output waveform of the detector 240 at the time when the multiple beams 20 are scanned by the slit 35 is further used, beam presence ranges in mutually orthogonal directions are able to be identified, so it is possible to further accurately identify the beam presence positions. It is also possible to detect an abnormality in the shape of a multiple beam distribution by comparing a₁ with a₂.

In the above-described embodiment, the example in which the two slits 33, 34 having different extending directions are provided has been described. Alternatively, as shown in FIG. 12, an opening 36 having two sides s1, s2 with different extending directions may be provided. In the example shown in FIG. 12, the side s1 extends in an inclination direction that makes an angle θ with the y direction, and the side s2 extends in the y direction.

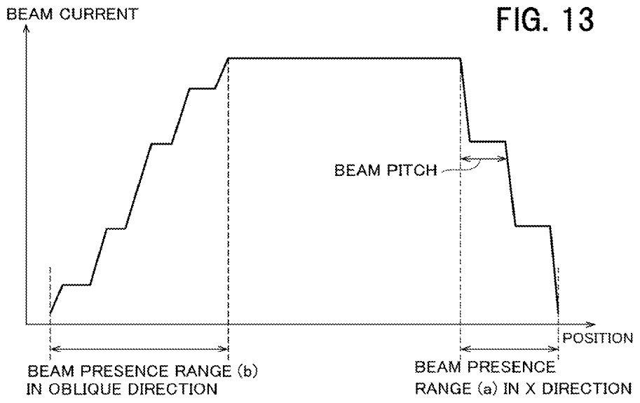

FIG. 13 shows an example of detection results of the detector 240 in the case where the beam selection aperture substrate 230 shown in FIG. 12 is moved in the negative x direction and the multiple beams 20 scan the opening 36 in the positive x direction. In scanning of the opening 36, the multiple beams 20 pass through the sides s1, s2 and cross the opening 36.

As shown in FIG. 13, from the output waveform of the detector 240, the beam pitch, the presence range a of multiple beams 20 in the x direction, and the presence range b of the multiple beams 20 in an oblique direction (a direction orthogonal to the extending direction of the side s1) are obtained.

Where a=D, and b=D(sin θ+cos θ), the multiple beams 20 and the beam selection aperture substrate 230 are in a right-angle parallel positional relationship, and a step interval of the waveform that appears in a stepwise manner is able to be identified as a beam pitch. The center beam position is the center of a center step position (in the graph, the second from the right) in an x-direction beam presence position of FIG. 13.

On the other hand, where a>D, and b<D(sin θ+cos θ), it is determined that the multiple beams 20 are rotated from the right-angle parallel positional relationship with the beam selection aperture substrate 230. When rotated, the absolute value of the rotational angle is obtained as in the case of the above-described embodiment; however, the rotation direction is not identified. The rotation direction is able to be identified from the shape of the output waveform of the detector 240 at the time when the side s1 passes through the multiple beams 20.

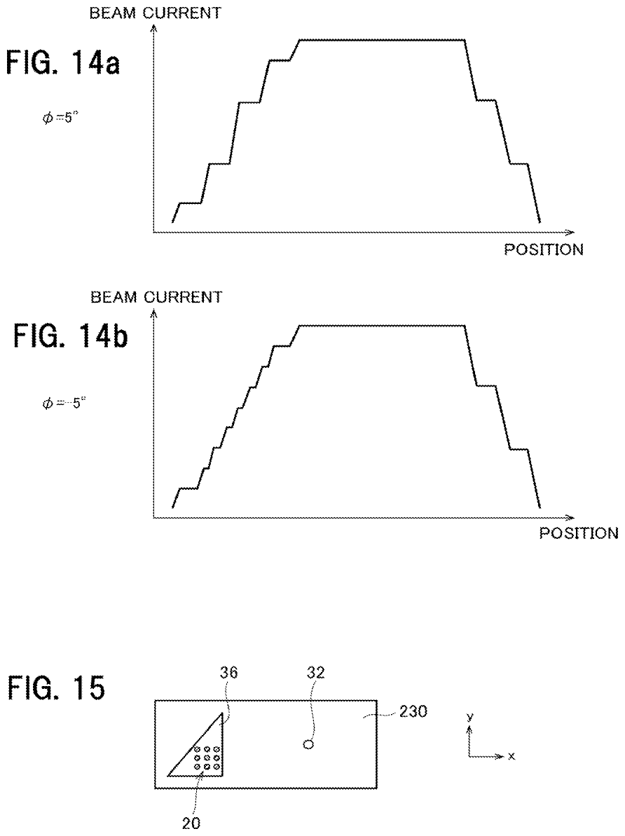

FIG. 14a shows a waveform in the case where the multiple beams 20 are inclined by 5° with respect to the beam selection aperture substrate 230. FIG. 14b shows a waveform in the case where the multiple beams 20 are inclined by −5° with respect to the beam selection aperture substrate 230. It is apparent that the number of steps of the waveform, formed by the side s1, is different. A rotational angle is determined by using the difference in waveform.

Specifically, the beam distribution calculation circuit 140 consults the scan waveform information prestored in the storage device 111, and uniquely determines the rotational angle φ of the multiple beams 20 from the number of steps of the output waveform of the detector 240 at the time when the side s1 of the opening 36 scans the multiple beams 20. The beam distribution calculation circuit 140 identifies the position of each of the beams of the multiple beams 20 by using the beam presence range, the beam pitch obtained from the expression 1, the rotational angle φ obtained from the output waveform, and the like.

The opening 36 preferably has a size such that the multiple beams 20 do not overlap the side s1 and the side s2 at the same time. The shape of the opening 36 is not limited to a triangle and may be a polygonal shape, such as a quadrangle and a pentagon.

As shown in FIG. 15, the opening 36 may also function as the large passage hole 31.

In the above-described embodiment, the configuration in which the current of each of beams having passed through the slits 33 to 35 and the opening 36 is detected with the detector 240 has been described; however, the configuration is not limited thereto. The beam selection aperture substrate 230 itself may function as a detector. In this case, obtained data is inverted (a current is observed only when beams are applied to the beam selection aperture substrate 230); however, beam positions are able to be identified with a similar procedure. The detector 240 may be installed as long as between the beam selection aperture substrate 230 and the multi-detector 222. For example, the multi-detector 222 may be used as the detector 240.

In the above-described embodiment, the example using electron beams has been described. Alternatively, another charged particle beam, such as ion beam, may be used.

Although the present invention has been described in detail by way of the specific modes, it is apparent for those skilled in the art that various changes can be made without departing from the spirit and scope of the present invention.

The present application is based on Japanese Patent Application No. 2020-138777 filed on Aug. 19, 2020, the entire contents of which are incorporated herein by reference.

### REFERENCE SIGNS LIST

20 multiple primary electron beams
31 large passage hole
32 small passage hole
33, 34, 35 slit
100 inspection apparatus
101 substrate
102 electron beam column
103 inspection chamber
201 electron gun
222 multi-detector
230 beam selection aperture substrate
300 multiple secondary electron beams

1. A multi-electron beam inspection apparatus comprising:
an electron gun discharging an inspection electron beam;
an aperture array substrate including a plurality of passage holes, wherein part of the inspection electron beam passes through each of the plurality of passage holes to form multiple electron beams;
a beam selection aperture substrate including a first passage hole that passes all the multiple electron beams, a second passage hole through which one of the multiple electron beams is able to pass, a first slit, and a second slit not parallel to the first slit;
an aperture moving unit moving the beam selection aperture substrate;
a first detector detecting a current of a beam having passed through the first slit and a current of a beam having passed through the second slit, of the multiple electron beams; and
a second detector detecting multiple secondary electron beams including reflected electrons, discharged from an inspected substrate mounted on a stage, due to application of the multiple electron beams, having passed through the first passage hole, to the inspected substrate, wherein
the inspected substrate is inspected based on an output signal from the second detector.

2. The multi-electron beam inspection apparatus according to claim 1, wherein
an extending direction of the first slit is orthogonal to a moving direction of the beam selection aperture substrate, and
an intersection angle θ between the extending direction of the first slit and an extending direction of the second slit is 0°<θ<45° or 45°<θ<90°.

3. The multi-electron beam inspection apparatus according to claim 2, wherein the intersection angle θ between the extending direction of the first slit and the extending direction of the second slit is larger than or equal to 5° and smaller than or equal to 44° or larger than or equal to 46° and smaller than or equal to 85°.

4. The multi-electron beam inspection apparatus according to claim 1, wherein the width of each of the first slit and the second slit is less than a value obtained by subtracting the size of one beam from a beam pitch of the multiple electron beams on a surface of the beam selection aperture substrate.

5. The multi-electron beam inspection apparatus according to claim 1, wherein the first slit and the second slit are spaced apart a beam size of the multiple electron beams or longer on a surface of the beam selection aperture substrate in order for different beams of the multiple electron beams not to respectively pass through the first slit and the second slit at a same time.

6. The multi-electron beam inspection apparatus according to claim 1, further comprising a beam distribution calculation circuit calculating a presence range, beam pitch, and rotational angle of the multiple electron beams by using movement amount information of the beam selection aperture substrate from the aperture moving unit and a detection signal from the first detector or the second detector.

7. The multi-electron beam inspection apparatus according to claim 6, wherein the aperture moving unit moves the beam selection aperture substrate such that only one specific beam of the multiple electron beams passes through the second passage hole, based on the presence range, beam pitch, and rotational angle of the multiple electron beams.

8. The multi-electron beam inspection apparatus according to claim 6, wherein
an extending direction of the first slit is orthogonal to a moving direction of the beam selection aperture substrate, and
the beam distribution calculation circuit calculates distribution information of the multiple electron beams in a direction orthogonal to the extending direction of the second slit based on detection results of currents of beams having passed through the second slit, and an intersection angle θ between the extending direction of the first slit and an extending direction of the second slit.

9. The multi-electron beam inspection apparatus according to claim 1, wherein
the beam selection aperture substrate further includes a third slit that extends in a direction orthogonal to an extending direction of the first slit,
the aperture moving unit moves the beam selection aperture substrate in a direction orthogonal to the extending direction of the first slit to make part of the multiple electron beams pass through the first slit and the second slit, and moves the beam selection aperture substrate in a direction parallel to the extending direction of the first slit to make part of the multiple electron beams pass through the third slit, and
the first detector detects currents of beams having passed through the first slit, a current of a beam having passed through the second slit, and a current of a beam having passed through the third slit.

10. A multi-electron beam inspection apparatus comprising:
an electron gun discharging an inspection electron beam;
an aperture array substrate including a plurality of passage holes, wherein part of the inspection electron beam passes through each of the plurality of passage holes to form multiple electron beams;
a beam selection aperture substrate including a first passage hole that passes all the multiple electron beams, a second passage hole through which one of the multiple electron beams is able to pass, and an opening having a first side and a second side not parallel to the first side;
an aperture moving unit moving the beam selection aperture substrate such that the multiple electron beams cross the opening through the first side and the second side;
a first detector detecting a current of a beam having passed through the opening, of the multiple electron beams; and
a second detector detecting multiple secondary electron beams including reflected electrons, discharged from an inspected substrate mounted on a stage, due to application of the multiple electron beams, having passed through the first passage hole, to the inspected substrate, wherein
the substrate is inspected based on an output signal from the second detector.

11. The multi-electron beam inspection apparatus according to claim 10, further comprising a beam distribution calculation circuit calculating a presence range, beam pitch, and rotational angle of the multiple electron beams by using movement amount information of the beam selection aperture substrate from the aperture moving unit and a detection signal from the first detector or the second detector.

12. The multi-electron beam inspection apparatus according to claim 11, wherein the aperture moving unit moves the beam selection aperture substrate such that only one specific beam of the multiple electron beams passes through the second passage hole, based on the presence range, beam pitch, and rotational angle of the multiple electron beams.

13. The multi-electron beam inspection apparatus according to claim 11, wherein
the first side extends in a direction inclined with respect to a moving direction of the beam selection aperture substrate,
the second side extends in a direction orthogonal to the moving direction, and
the beam distribution calculation circuit obtains the beam pitch of the multiple electron beams, the presence range of the multiple electron beams in the moving direction, and the presence range of the multiple electron beams in a direction orthogonal to an extending direction of the first side, from an output waveform of the first detector or the second detector.

14. The multi-electron beam inspection apparatus according to claim 13, wherein the beam distribution calculation circuit obtains a rotational angle of the multiple electron beams from the shape of the output waveform of the first detector or the second detector, and the number of steps of an output waveform of the first detector or the second detector when the first side is scanned with the multiple electron beams.

15. An adjustment method for a multi-electron beam inspection apparatus that inspects a pattern by detecting multiple secondary electron beams including reflected electrons, discharged from a substrate having a formed pattern, due to application of multiple electron beams to the substrate, and using information of the detected multiple secondary electron beams, the adjustment method comprising:
a step of, while moving, in a predetermined direction, a beam selection aperture substrate including a passage hole through which one of the multiple electron beams is able to pass, a first slit, and a second slit not parallel to the first slit, detecting a current of a beam having passed through the first slit, of the multiple electron beams;
a step of, while moving the beam selection aperture substrate in the predetermined direction, detecting a current of a beam having passed through the second slit, of the multiple electron beams;
a step of calculating distribution information of the multiple electron beams based on detection results of currents of beams having passed through the first slit and detection results of currents of beams having passed through the second slit;
a step of aligning a predetermined beam of the multiple electron beams with the passage hole by moving the beam selection aperture substrate based on the distribution information of the multiple electron beams; and
a step of performing beam adjustment by using a beam having passed through the passage hole.

16. The adjustment method for a multi-electron beam inspection apparatus according to claim 15, wherein
an extending direction of the first slit is orthogonal to the predetermined direction, and
an intersection angle θ between the extending direction of the first slit and an extending direction of the second slit is 0°<θ<45° or 45°<θ<90°.

17. The adjustment method for a multi-electron beam inspection apparatus according to claim 16, wherein the intersection angle θ between the extending direction of the first slit and the extending direction of the second slit is larger than or equal to 5° and smaller than or equal to 44° or larger than or equal to 46° and smaller than or equal to 85°.

18. The adjustment method for a multi-electron beam inspection apparatus according to claim 16, wherein the distribution information of the multiple electron beams in a direction orthogonal to an extending direction of the second slit is calculated based on detection results of currents of beams having passed through the second slit, and the intersection angle θ.

19. The adjustment method for a multi-electron beam inspection apparatus according to claim 15, wherein the width of each of the first slit and the second slit is less than a value obtained by subtracting the size of one beam from a beam pitch of the multiple electron beams on a surface of the beam selection aperture substrate.

20. The adjustment method for a multi-electron beam inspection apparatus according to claim 15, wherein the first slit and the second slit are spaced apart a beam size of the multiple electron beams or longer on a surface of the beam selection aperture substrate in order for different beams of the multiple electron beams not to respectively pass through the first slit and the second slit at a same time.
